(19) United States
(12) Patent Application Publication
(10) Pub. No.: US 2024/0282399 A1
(43) Pub. Date: Aug. 22, 2024

(54) OPTIMIZING READ ERROR HANDLING IN A MEMORY SUB-SYSTEM

(71) Applicant: Micron Technology, Inc., Boise, ID (US)

(72) Inventor: Kyungjin Kim, San Jose, CA (US)

(21) Appl. No.: 18/429,753

(22) Filed: Feb. 1, 2024

Related U.S. Application Data
(60) Provisional application No. 63/486,125, filed on Feb. 21, 2023.

(51) Int. Cl. G11C 29/52; G11C 16/26; G11C 16/34

(52) U.S. Cl. CPC G11C 29/52; G11C 16/26; G11C 16/3459

(57) ABSTRACT

A request to perform a read operation on a multi-bit memory cell is received. A read operation on a respective page of the multi-bit memory cell is performed for each page of the multi-bit memory cell. Whether the respective page is at least one of either a lower logical page (LP) or an upper logical page (UP) of the multi-bit memory cell is determined responsive to determining that the read operation on the respective page failed. A read error handling operation on the respective page is performed. A read level associated with a successful read of the respective page is obtained from the read error handling operation. An ordering of a plurality of entries of a read retry data structure associated with the read error handling operation is rearranged based on the obtained read level responsive to determining that the respective page is the LP or UP.

### RELATED APPLICATIONS

This application claims the benefit of U.S. Provisional Patent Application No. 63/486,125, filed Feb. 21, 2023, entitled “OPTIMIZING READ ERROR HANDLING IN A MEMORY SUB-SYSTEM,” which is incorporated by reference herein.

### TECHNICAL FIELD

Embodiments of the disclosure relate generally to memory sub-systems, and more specifically, relate to optimizing read error handling in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2A illustrates an example of a table storing a plurality of read levels for each read retry operation of a read error handling operation, in accordance with some embodiments of the present disclosure.

FIG. 2B illustrates an example of a table storing a plurality of read levels for each read retry operation of a read error handling operation optimized for charge loss experienced by a previous page, in accordance with some embodiments of the present disclosure.

FIG. 2C illustrates an example of a table storing a plurality of read levels for each read retry operation of a read error handling operation optimized for charge gain experienced by a previous page, in accordance with some embodiments of the present disclosure.

FIG. 3 illustrates a flow diagram of an example method of optimizing read error handling in a memory sub-system, in accordance with some embodiments of the present disclosure.

FIG. 4 is a block diagram of an example computer system in which embodiments of the present disclosure may operate.

### DETAILED DESCRIPTION

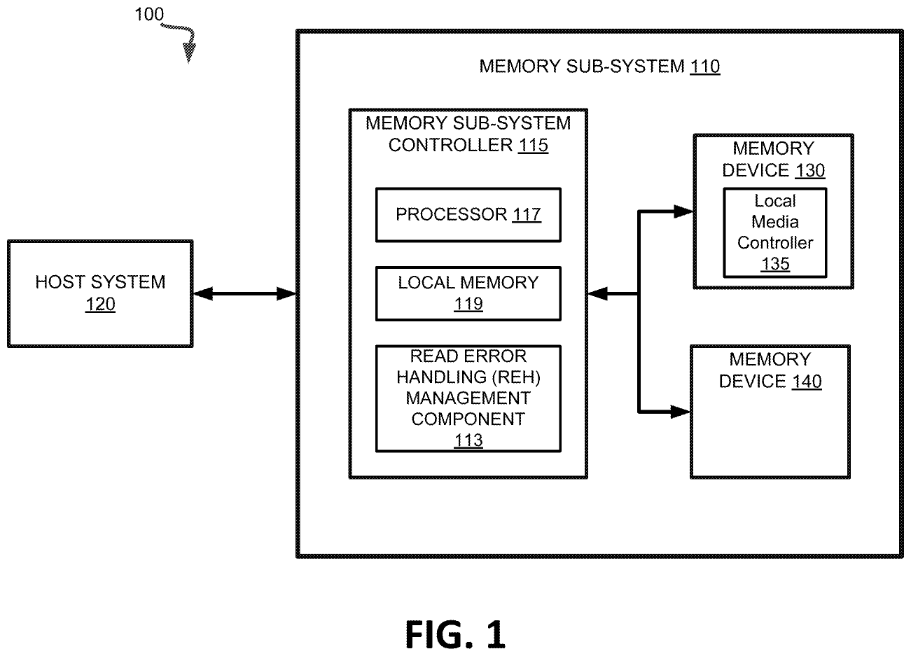

Aspects of the present disclosure are directed to optimizing an error recovery process in a memory sub-system. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can includes of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can have a row of associated memory cells in a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For case of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

The memory device can store an amount of charge into the memory cells based on a programming level voltage or threshold voltage (V_{T}) corresponding to multiple programming distributions associated with respective data values. The memory device can read or determine data values stored in the memory cells using a read level voltage (also referred to as a “read level”) corresponding to the threshold voltage for each programming distribution of the memory cell.

One type of memory cell (“cell”) is a single level cell (SLC), which stores 1 bit per cell and defines 2 logical states (“states”) (“1” or “L0” and “0” or “L1”) each corresponding to a respective VT level. For example, the “1” state can be an erased state and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”) each corresponding to a respective VT level. For example, the “11” state can be an erased state and the “01”, “10” and “00” states can each be a respective programmed state. Another type of cell is a triple level cell (TLC), which stores 3 bits per cell and defines 8 states (“111” or “L0”, “110” or “L1”, “101” or “L2”, “100” or “L3”, “011” or “L4”, “010” or “L5”, “001” or “L6”, and “000” or “L7”) each corresponding to a respective V_{T} level. For example, the “111” state can be an erased state and each of the other states can be a respective programmed state. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2ⁿ levels of charge to store n bits. A memory device can include one or more arrays of memory cells such as SLCs, MLCs, TLCs, QLCS, PLCs, etc. or any combination of such.

Each bit is stored at a different portion (also referred to as “logical page” hereafter) of the memory cell. Various read levels can be used for the various logical page types (also referred to as “page types” herein): SLC logical page types are lower logical pages (LPs), MLC logical page types are LPs, and upper logical pages (UPs), TLC logical page types are LPs, UPs, and extra logical pages (XPs), and QLC logical page types are LPs, UPs, XPs and top logical pages (TPs), and so on. Each threshold voltage of a threshold voltage distribution corresponds to a logical page of the memory cell. For example, a first threshold voltage (e.g., V1) and fifth threshold voltage (e.g., V5) correspond to LPs of the TLC; a second threshold voltage (e.g., V2), a fourth threshold voltage (e.g., V4), and a sixth threshold voltage (e.g., V6) correspond to UPs of the TLC; and a third threshold voltage (e.g., V3) and seventh threshold voltage (e.g., V7) correspond to XPs of the TLC.

Due to various physical phenomena and operational processes, such as slow charge loss and read disturb, charge levels of memory cells may degrade in time, thus causing higher error rates in memory read operations. Read disturb is a phenomenon where reading data from a memory cell can cause the threshold voltage levels of unread memory cells in the same block to shift to a different value. Slow charge loss is a phenomenon where the threshold voltage level of a memory cell changes in time as the electric charge of the memory cell degrades.

The resulting memory degradation can be measured by various data state metrics. “Data state metric” herein shall refer to a quantity that is measured or inferred from the state of data stored on a memory device. Specifically, the data state metrics may reflect the state of the slow charge loss, the degree of latent read disturb, the temporal voltage shift, and/or other measurable functions of the data state. In an illustrative example, the data state metric can be represented by the raw bit error rate (RBER), which is the number of bit errors experienced by a given data block per unit of time.

In order to mitigate the memory degradation, data integrity check operations (also referred to herein as “media scan operations”) can be periodically performed on the memory device. In an illustrative example, the media scan operation evaluates one or more data state metrics on a block of the memory device.

The media scan operation measures a data state metric of the page and triggers a read level calibration (or auto read calibration (ARC)) if the measured data state metric of the page exceeds an initial predefined data state metric threshold. Read level calibration is one mechanism that can be used by a controller to identify a calibrated read level for reading target cells connected to a target wordline. Read level calibration can be performed by analyzing threshold voltage (Vₜ) distributions of a group of cells to obtain a model (e.g., histogram) describing the Vₜ distributions, and identifying the calibrated read level from the model.

The media scan operations, using the calibrated read level, measure a data state metric of the page and triggers a media management operation if the measured data state metric exceeds a final predefined data state metric threshold. In an illustrative example, the media management operations can include refresh, or “folding,” operations, which involve relocating the data stored at an affected block of the memory device to another block. Otherwise, depending on the memory cell, the media scan operation proceeds to the next page of the block in a sequential manner (e.g., from LP to UP to XP) to further evaluate the block.

Typically, during media scan operations of a block, there is a high likelihood that if a first page (e.g., the LP) enters read level calibration, other pages (e.g., UP, XP, and TP) also enter read level calibration. Further, there is a high correlation between the calibrated read level obtained for LP and that of other pages (e.g., UP, XP, and TP). In an illustrative example, since the calibrated read level obtained for LP may mitigate against charge loss experienced by the block, the other pages may also need to mitigate against the same charge loss experienced by the block. Thus, the calibrated read level of the LP and the other pages typically have the same direction (e.g., negative direction or positive direction).

During sequential read of a block, if the first page of the block (e.g. LP) fails, the memory sub-system enters read error handling (REH) to recover data. The read error handling can include different techniques such as read retry, coarse threshold estimation (CTE), sure auto read calibration (ARC), or soft-decision decoding (e.g., 1 hard bits (H)/2 soft bits (S) (1H2S)). The read error handling may recover data using an obtained read level. Similarly, based on the high correlation between the calibrated read level obtained for LP and that of other pages as indicated by the media scan, there is a high chance that the other pages will also fail and result in an obtained read level with a similar direction as LP. However, no information regarding the failure of the previous page or the direction of the obtained read level is used during read error handling for subsequent pages of the block.

Aspects of the present disclosure address the above and other deficiencies by modifying a read retry table (RRT) used during read error handling (e.g. read error handling operation) based on a read level obtained during an REH operation. In one embodiment, responsive to receiving a read operation on a page of a multi-bit memory cell, the memory sub-system determines whether the page of the multi-bit memory cell has failed. A multi-bit memory cell may be a MLC, TLC, QLC, or PLC. Responsive to determining that the page of the multi-bit memory cell has failed, the memory sub-system determines whether the page is at least one of either a lower logical page (LP) of the multi-bit memory cell or an upper logical page (UP) of the multi-bit memory cell. Responsive to determining that the page is the LP or the UP, the memory sub-system performs an REH operation to recover the data of the page. The memory sub-system identifies, from the REH operation, a read level used to recover the data.

The memory sub-system determines a direction (e.g., positive or negative) of the read level. The directions of a read level may be negative if the value of the read level is negative and positive if the value of the read level is positive. The memory sub-system rearranges a read retry data structure (e.g., read retry table) based on the direction of the read level.

The read retry table (RRT) includes a plurality of entries with a predetermined order. Each entry of the plurality of entries includes a plurality of read levels. Each read level of the plurality of read levels refers to a threshold voltage of a plurality of threshold voltages. Each threshold voltage is associated with a page of the multi-bit memory cell. Accordingly, during REH operations, a read level is obtained sequentially from a first entry of the RRT to the last entry of the RRT based on the threshold voltages associated with the page being read.

If the direction of the read level is positive, the memory sub-system rearranges the plurality of entries of the RRT by prioritizing positive read levels. For example, starting with the first entry of the plurality of entries, each entry is examined to determine if a value of the read level at a specified threshold voltage (associated with a specified page of the multi-bit memory cell) is positive or negative. The specified page corresponding to the specified threshold voltage may be a threshold voltage associated with a first page of the multi-bit memory cell, a predetermined page of the multi-bit memory cell, or the current page of the multi-bit memory cell. If the value of the read level at the specified threshold voltage of a respective entry is positive, the respective entry is sequentially added to the top of the RRT. As a result, a subset of the plurality of entries with a positive read level at the specified threshold voltage is moved to the top of the RRT with their ordering maintained and the subset of the plurality of entries with a zero and/or negative read level at the specified threshold voltage remains at the bottom of the RRT with their ordering maintained.

If the direction of the read level is negative, the memory sub-system rearranges the plurality of entries of the RRT by prioritizing negative read levels. For example, starting with the first entry of the plurality of entries, each entry is examined to determine if a value of the read level at a specified threshold voltage (associated with a specified page of the multi-bit memory cell) is positive or negative. The specified page corresponding to the specified threshold voltage may be a threshold voltage associated with a first page of the multi-bit memory cell, a predetermined page of the multi-bit memory cell, or the current page of the multi-bit memory cell. If the value of the read level at the specified threshold voltage of a respective entry is negative, the respective entry is sequentially added to the top of the RRT. As a result, a subset of the plurality of entries with a negative read level at the specified threshold voltage is moved to the top of the RRT with their ordering maintained and the subset of the plurality of entries with a zero and/or positive read level at the specified threshold voltage remains at the bottom of the RRT with their ordering maintained.

Consequently, when a read operation on a subsequent page of the multi-bit memory cell fails and an REH operation is triggered, the REH operation employs a read level from each entry in the rearranged RRT sequentially at a threshold voltage associated with the subsequent page in order to recover the data from the subsequent page.

Advantages of the present disclosure include, but are not limited to, improving memory device performance, and quality of service. Since other pages (e.g., upper page, extra page, etc.) are likely to have a read level of the same direction (e.g, positive or negative value) as a prior page (e.g., a lower page), prioritizing entries of the RRT having the same direction as the prior page will increase efficiency of the REH operation. In particular, read levels from each entry having the same direction as the prior page is utilized in the REH operation for subsequent pages prior to those with a different (or opposite) direction.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a read error handling management (REH) component 113 that rearranges a read retry table (RRT) used during REH operations based on information from a previous REH operation. In some embodiments, the memory sub-system controller 115 includes at least a portion of the REH management component 113. In some embodiments, the REH management component 113 is part of the host system 120, an application, or an operating system. In other embodiments, local media controller 135 includes at least a portion of REH management component 113 and is configured to perform the functionality described herein.

The REH management component 113 identifies whether a read operation performed on a page of a multi-bit memory cell (e.g., TLC) of memory device 130 and/or 140 has failed. The REH management component 113 performs an REH operation to recover the data from the page of the multi-bit memory cell. A multi-bit memory cell may be a TLC having a LP, UP, and XP. The REH management component 113 determines whether the page is a LP or a UP of the multi-bit memory cell. As noted above, each logical page of the memory cell is associated with a threshold voltage of a threshold voltage distribution corresponds. For example, a first threshold voltage (e.g., V1) and fifth threshold voltage (e.g., V5) correspond to LPs of the TLC; a second threshold voltage (e.g., V2), a fourth threshold voltage (e.g., V4), and a sixth threshold voltage (e.g., V6) correspond to UPs of the TLC; and a third threshold voltage (e.g., V3) and seventh threshold voltage (e.g., V7) correspond to XPs of the TLC. Accordingly, based on the threshold voltage, the REH management component 113 may determine whether the page is an LP, UP, or XP. Responsive to determining that the page is a LP or UP, the REH management component 113 identifies a read level used to recover the data from the page. The REH management component 113 further identifies a direction of the read level. The direction of the read level is positive if the value of the read level is positive and negative if the value of the read level is negative.

The REH management component 113 rearranges, based on the direction of the read level, a read retry data structure (e.g., read retry table (RRT)) stored in local memory 119 or in memory device 130 and/or 140. As noted above, the RRT includes a plurality of entries. Each entry of the plurality of entries includes a plurality of threshold voltages. Each threshold voltage of the plurality of threshold voltages refers to a read level used to recover a page of the multi-bit memory cell.

If the direction of the read level is positive, the REH management component 113 identifies entries of the RRT in which a read level associated with a specified threshold voltage (associated with a specified page of the multi-bit memory cell) is a positive value. The specified page corresponding to the specified threshold voltage may be a threshold voltage associated with a first page of the multi-bit memory cell, a predetermined page of the multi-bit memory cell, or the current page of the multi-bit memory cell. The ordering of the entries identified as having a positive value are maintained and moved to the beginning (or top) of the RRT. As a result, the remaining entries (e.g., entries having a negative or zero value) will be left in their current order and will remain at the end (or bottom) of the RRT.

If the direction of the read level is negative, the REH management component 113 identifies entries of the RRT in which a read level associated with a specified threshold voltage (associated with a specified page of the multi-bit memory cell) is a negative value. The specified page corresponding to the specified threshold voltage may be a threshold voltage associated with a first page of the multi-bit memory cell, a predetermined page of the multi-bit memory cell, or the current page of the multi-bit memory cell. The ordering of the entries identified as having a negative value are maintained and moved to the beginning (or top) of the RRT. As a result, the remaining entries (e.g., entries having a positive or zero value) will be left in their current order and will remain at the end (or bottom) of the RRT.

Once the RRT is rearranged, if a subsequent REH operation is triggered to recover data of a page, the REH operation recovers the data of the page using the rearranged RRT. Specifically, the REH operation retrieves from each entry of the plurality of entries of the rearranged RRT a read level associated with the page. Each read level retrieved from a respective entry is used to perform a read operation on the page. If the read operation is successful, the read level of the respective entry used is the new read level for the page. Further details with regards to the operations of the REH management component 113 are described below.

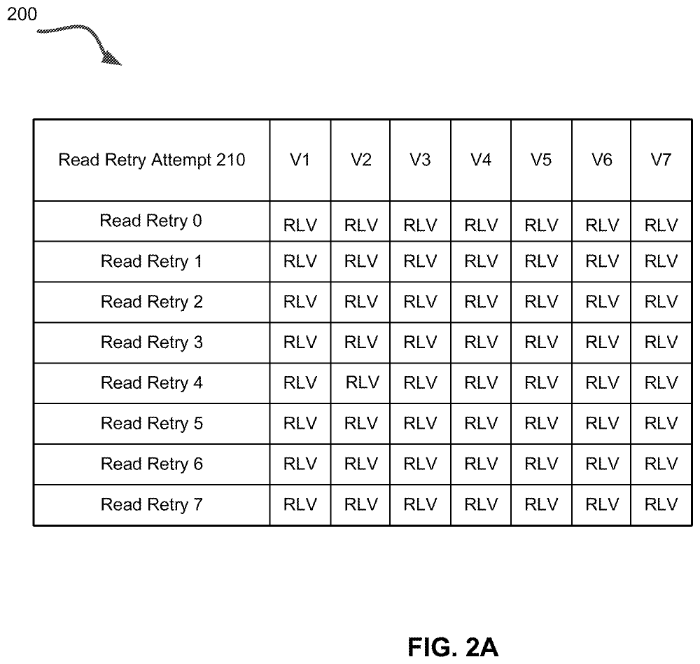

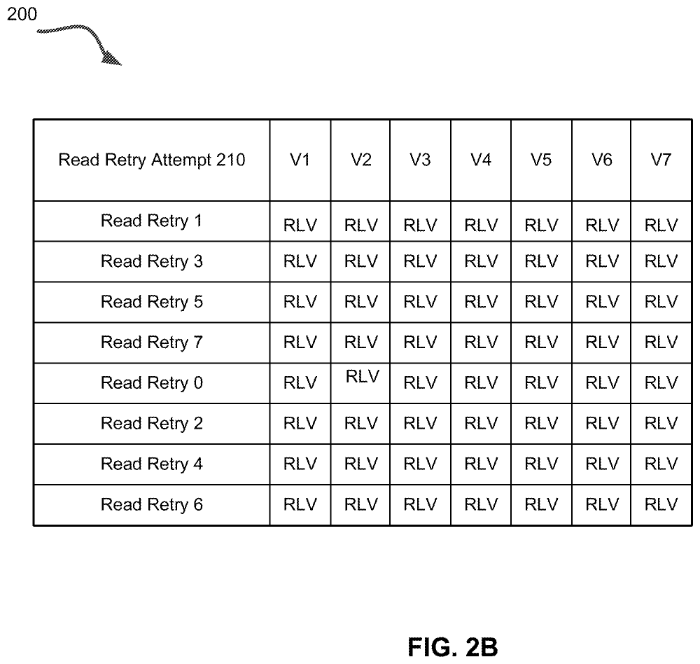

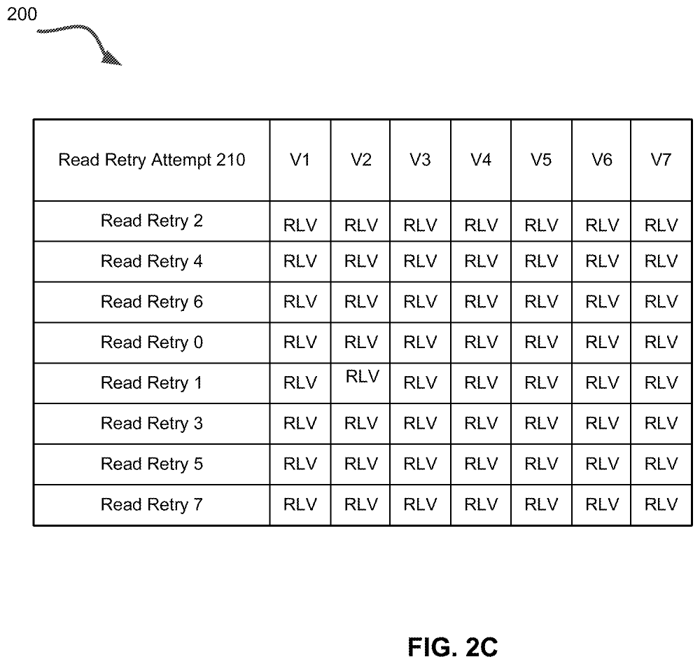

FIG. 2A-C illustrates an example read retry data structure (e.g., table) (RRT) 200 that provides, REH operations, read level values used to recover data of a page of a multi-bit memory cell, in accordance with some embodiments of the present disclosure. In one embodiment, RRT 200 is stored in the local memory 119 of the memory sub-system 110 or in memory device 130 and/or 140. The RRT 200 includes multiple rows identified by a read retry attempt 210. Each read retry attempt 210 corresponds each read retry performed by the REH operation to recover the data. The RRT 200 includes multiple columns (e.g., threshold voltages V1-7) each identified by a threshold voltage of a plurality of threshold voltages. Each threshold voltage is associated with a page of the multi-bit memory cell. Each entry of the RRT 200 identified by a read retry attempt 210 and a threshold voltage of the plurality of threshold voltages (e.g., V1-7) includes a read level value (RLV) used to recover data of a page of the multi-bit memory cell associated with the threshold voltage. Referring to FIG. 2A, prior to the REH management component 113, the multiple rows identified by the read retry attempt 210 are in a predetermined order (e.g., read retry 0-7).

Referring now to FIG. 2B, RRT 200 is rearranged based on a positive direction of the read level (e.g., RLV) obtained from a previous REH operation. As previously described, a positive direction refers to an RLV having a positive value. Accordingly, the REH management component 113 of FIG. 1 rearranged the multiple rows by identifying entries of the RRT 200 in which the RLV associated with a specific page (or threshold voltage) is a positive value (e.g., read retry 1, 3, 5, and 7). The identified entries are moved, with their ordering maintained, to the beginning (or top) of the RRT 220. As a result, the remaining entries in which the RLV associated with the specific page is a negative value (e.g., read retry 2, 4, and 6) or a zero value (e.g., read retry 0) remain at the end (or bottom) of the RRT 220 with their ordering maintained. According, in operation, when a REH operation is triggered, the REH management operations will retrieve a RLV from the RRT 200 from the first entry to the last entry despite the reordering (i.e., a RLV is retrieved from read retry 1, 3, 5, 7, 0, 2, 4, and 6).

Referring now to FIG. 2C, RRT 200 is rearranged based on a negative direction of the read level (e.g., RLV) obtained from a previous REH operation. As previously described, a negative direction refers to an RLV having a negative value. Accordingly, the REH management component 113 of FIG. 1 rearranged the multiple rows by identifying entries of the RRT 200 in which the RLV associated with a specific page (or threshold voltage) is a negative value (e.g., read retry 2, 4, and 6). The identified entries are moved, with their ordering maintained, to the beginning (or top) of the RRT 220. As a result, the remaining entries in which the RLV associated with the specific page is a positive value (e.g., read retry 1, 3, 5, and 7) or a zero value (e.g., read retry 0) remain at the end (or bottom) of the RRT 220 with their ordering maintained. According, in operation, when a REH operation is triggered, the REH management operations will retrieve a RLV from the RRT 200 from the first entry to the last entry despite the reordering (i.e., a RLV is retrieved from read retry 2, 4, 6, 0, 1, 3, 5, and 7).

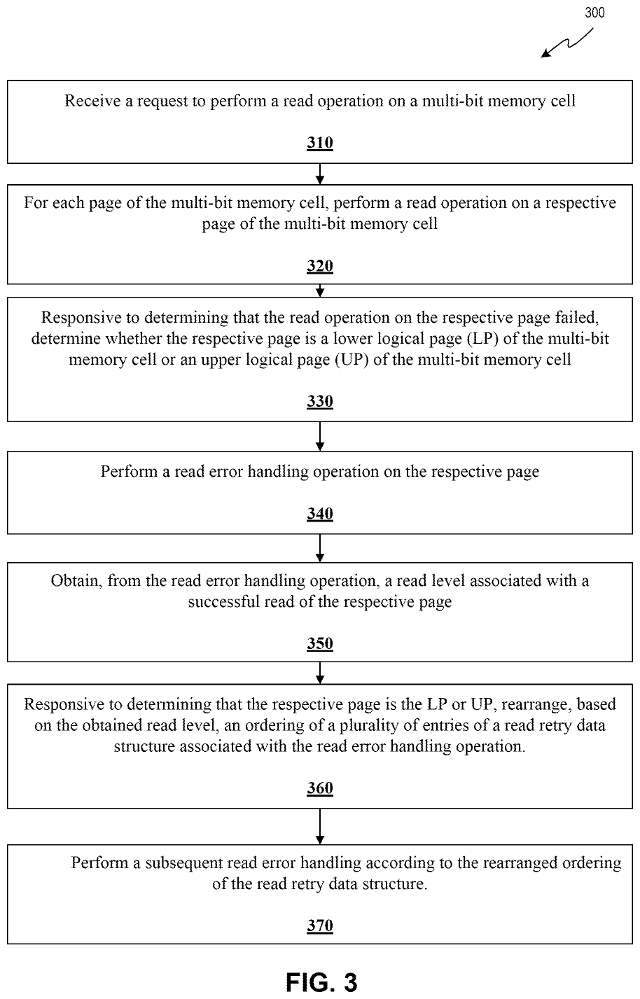

FIG. 3 is a flow diagram of an example method 300 of optimizing read error handling, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the REH management component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 310, the processing logic receives a request to perform a read operation on a multi-bit memory cell. At operation 320, for each page of the multi-bit memory cell, the processing logic performs a read operation on a respective page of the multi-bit memory cell.

At operation 330, responsive to determining that the read operation on the respective page failed, the processing logic determines whether the respective page is at least one of either a lower logical page (LP) of the multi-bit memory cell or an upper logical page (UP) of the multi-bit memory cell. The multi-bit memory cell may include at least one of a LP, a UP, an extra logical page (XP), and a top logical page (TP). The page may be determined based on the threshold voltages. As previously described, each threshold voltage corresponds to a logical page of the multi-bit memory cell. For example, if the threshold voltage is a first and/or fifth threshold voltage, the page is a UP.

At operation 340, the processing logic performs a read error handling operation on the respective page. In some embodiments, the REH operations include for each entry of the read retry data structure, performing, using a read level of a plurality of read levels associated with a respective entry, a read operation on the respective page. The REH operation determines whether the read operation, using the read level of the plurality of read levels, is successful. At operation 350, the processing logic obtains, from the read error handling, a read level associated with a successful read of the respective page. The obtained read level is used to recover data from the respective page and successfully read the respective page. The read level of the respective page is updated with the obtained read level. Depending on the embodiment, the read error handling (REH) operation may be a coarse threshold estimation (CTE), sure auto read calibration (ARC), or soft-decision decoding.

At operation 360, responsive to determining that the respective page is the LP or UP, the processing logic rearranges, based on the obtained read level, an ordering of a plurality of entries of a read retry data structure associated with the read error handling operation. As previously described, the read retry data structure (e.g., read retry table (RRT)) includes a plurality of entries. Each entry of the plurality of entries include a plurality of read levels. Each read level can be used to read a page of the multi-bit memory cell. The read retry data structure is rearranged based on a direction of the obtained read level. The direction of the obtained read level is positive if the value of the read level is positive and negative if the value of the read level is negative.

Responsive to determining that the obtained read level has a negative direction, the processing logic arranges the entries of the read retry data structure with negative values before the entries of the read retry data structure with positive values. As previously described, entries of the read retry data structure in which a read level associated with a specified threshold voltage (e.g., a threshold voltage associated with a first page of the multi-bit memory cell, a predetermined page of the multi-bit memory cell, or the current page of the multi-bit memory cell) is a negative value are moved to the beginning (or top) of the read retry data structure with their ordering maintained. As a result, the remaining entries (e.g., entries having a positive or zero value) will be left in their current order and will remain at the end (or bottom) of the read retry data structure.

Responsive to determining that the obtained read level has a positive direction, the processing logic arranges the entries of the read retry data structure with positive values before the entries of the read retry data structure with negative values. As previously described, entries of the read retry data structure in which a read level associated with a specified threshold voltage (e.g., a threshold voltage associated with a first page of the multi-bit memory cell, a predetermined page of the multi-bit memory cell, or the current page of the multi-bit memory cell) is a positive value are moved to the beginning (or top) of the read retry data structure with their ordering maintained. As a result, the remaining entries (e.g., entries having a negative or zero value) will be left in their current order and will remain at the end (or bottom) of the read retry data structure.

At operation 370, the processing logic performs a subsequent read error handling according to the rearranged ordering of the read retry data structure (e.g., rearranged read retry data structure). As previously described, the read error handling retries one or more read levels from each entry of the read retry data structure until a read operation of the page is successful. In particular, the processing logic retries a read operation with a read level from each entry of the rearranged read retry data structure associated with the page from a first entry of the rearranged read retry data structure to a last entry of the rearranged read retry data structure. Once the read operation is successful, the read level used to successfully read the page is updated as the new read level for the page. Depending on the embodiment, the new read level is used to rearrange the read retry data structure.

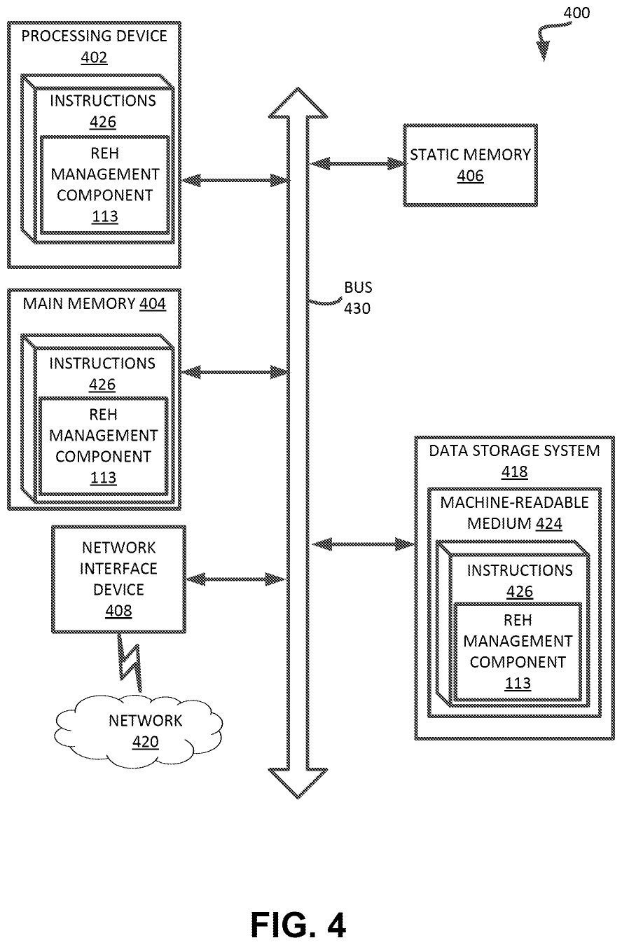

FIG. 4 illustrates an example machine of a computer system 400 within which a set of instructions, for causing the machine to perform any one or more of the methodologies discussed herein, can be executed. In some embodiments, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the REH management component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., read-only memory (ROM), flash memory, dynamic random access memory (DRAM) such as synchronous DRAM (SDRAM) or RDRAM, etc.), a static memory 406 (e.g., flash memory, static random access memory (SRAM), etc.), and a data storage system 418, which communicate with each other via a bus 430.

Processing device 402 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 402 can also be one or more special-purpose processing devices such as an application specific integrated circuit (ASIC), a field programmable gate array (FPGA), a digital signal processor (DSP), network processor, or the like. The processing device 402 is configured to execute instructions 426 for performing the operations and steps discussed herein. The computer system 400 can further include a network interface device 408 to communicate over the network 420.

The data storage system 418 can include a machine-readable storage medium 424 (also known as a computer-readable medium) on which is stored one or more sets of instructions 426 or software embodying any one or more of the methodologies or functions described herein. The instructions 426 can also reside, completely or at least partially, within the main memory 404 and/or within the processing device 402 during execution thereof by the computer system 400, the main memory 404 and the processing device 402 also constituting machine-readable storage media. The machine-readable storage medium 424, data storage system 418, and/or main memory 404 can correspond to the memory sub-system 110 of FIG. 1.

In one embodiment, the instructions 426 include instructions to implement functionality corresponding to a REH management component (e.g., the REH management component 113 of FIG. 1). While the machine-readable storage medium 424 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
receiving a request to perform a read operation on a multi-bit memory cell;
for each page of the multi-bit memory cell, performing a read operation on a respective page of the multi-bit memory cell;
responsive to determining that the read operation on the respective page failed, determining whether the respective page is at least one of either a lower logical page (LP) of the multi-bit memory cell or an upper logical page (UP) of the multi-bit memory cell;
performing a read error handling operation on the respective page;
obtaining, from the read error handling operation, a read level associated with a successful read of the respective page; and
responsive to determining that the respective page is the LP or UP, rearranging, based on the obtained read level, an ordering of a plurality of entries of a read retry data structure associated with the read error handling operation.

2. The method of claim 1, wherein each entry of the plurality of entries comprises a plurality of read levels, and wherein each read level of the plurality of read levels refers to a threshold voltage of the multi-bit memory cell.

3. The method of claim 1, further comprising:
performing a subsequent read error handling according to the rearranged ordering of the read retry data structure.

4. The method of claim 1, wherein the read error handling operation comprises:
for each entry of the read retry data structure, performing, using a read level of a plurality of read levels associated with a respective entry, a read operation on the respective page; and
determining whether the read operation, using the read level of the plurality of read levels, is successful.

5. The method of claim 1, wherein rearranging, based on the obtained read level, the ordering of the read retry data structure associated with the read error handling operation comprises:
responsive to determining that the obtained read level is a negative value, arranging the entries of the read retry data structure with negative values before the entries of the read retry data structure with positive values.

6. The method of claim 1, wherein rearranging, based on the obtained read level, the ordering of the read retry data structure associated with the read error handling operation comprises:
responsive to determining that the obtained read level is a positive value, arranging the entries of the read retry data structure with positive values before the entries of the read retry data structure with negative values.

7. The method of claim 1, further comprising:
updating the read level of the respective page with the obtained read level.

8. A system comprising:
a memory device; and
a processing device, operatively coupled to the memory device, the processing device to perform operations comprising:
receiving a request to perform a read operation on a multi-bit memory cell;
for each page of the multi-bit memory cell, performing a read operation on a respective page of the multi-bit memory cell;
responsive to determining that the read operation on the respective page failed, determining whether the respective page is a lower logical page (LP) of the multi-bit memory cell or an upper logical page (UP) of the multi-bit memory cell;
performing a read error handling operation on the respective page;
obtaining, from the read error handling operation, a read level associated with a successful read of the respective page; and
responsive to determining that the respective page is the LP or UP, rearranging, based on the obtained read level, an ordering of a plurality of entries of a read retry data structure associated with the read error handling operation.

9. The system of claim 8, wherein each entry of the plurality of entries comprises a plurality of read levels, and wherein each read level of the plurality of read levels reads a page of the multi-bit memory cell.

10. The system of claim 8, wherein the processing device to perform operations further comprising:
performing a subsequent read error handling according to the rearranged ordering of the read retry data structure.

11. The system of claim 8, wherein the read error handling operation comprises:
for each entry of the read retry data structure, performing, using a read level of a plurality of read levels associated with a respective entry, a read operation on the respective page; and
determining whether the read operation, using the read level of the plurality of read levels, is successful.

12. The system of claim 8, wherein rearranging, based on the obtained read level, the ordering of the read retry data structure associated with the read error handling operation comprises:
responsive to determining that the obtained read level is a negative value, arranging the entries of the read retry data structure with negative values before the entries of the read retry data structure with positive values.

13. The system of claim 8, wherein rearranging, based on the obtained read level, the ordering of the read retry data structure associated with the read error handling operation comprises:
responsive to determining that the obtained read level is a positive value, arranging the entries of the read retry data structure with positive values before the entries of the read retry data structure with negative values.

14. The system of claim 8, wherein the processing device to perform operations further comprising:
updating the read level of the respective page with the obtained read level.

15. A non-transitory computer readable storage medium including instructions that, when executed by a processing device, cause the processing device to perform a method comprising:
receiving a request to perform a read operation on a multi-bit memory cell;
for each page of the multi-bit memory cell, performing a read operation on a respective page of the multi-bit memory cell;
responsive to determining that the read operation on the respective page failed, determining whether the respective page is a lower logical page (LP) of the multi-bit memory cell or an upper logical page (UP) of the multi-bit memory cell;
performing a read error handling operation on the respective page;
obtaining, from the read error handling operation, a read level associated with a successful read of the respective page; and
responsive to determining that the respective page is the LP or UP, rearranging, based on the obtained read level, an ordering of a plurality of entries of a read retry data structure associated with the read error handling operation.

16. The non-transitory computer readable storage medium of claim 15, wherein each entry of the plurality of entries comprises a plurality of read levels, and wherein each read level of the plurality of read levels reads a page of the multi-bit memory cell.

17. The non-transitory computer readable storage medium of claim 15, wherein the method further comprises:
performing a subsequent read error handling according to the rearranged ordering of the read retry data structure.

18. The non-transitory computer readable storage medium of claim 15, wherein the read error handling operation comprises:
for each entry of the read retry data structure, performing, using a read level of a plurality of read levels associated with a respective entry, a read operation on the respective page; and
determining whether the read operation, using the read level of the plurality of read levels, is successful.

19. The non-transitory computer readable storage medium of claim 15, wherein rearranging, based on the obtained read level, the ordering of the read retry data structure associated with the read error handling operation comprises:
responsive to determining that the obtained read level is a negative value, arranging the entries of the read retry data structure with negative values before the entries of the read retry data structure with positive values.

20. The non-transitory computer readable storage medium of claim 15, wherein rearranging, based on the obtained read level, the ordering of the read retry data structure associated with the read error handling operation comprises:
responsive to determining that the obtained read level is a positive value, arranging the entries of the read retry data structure with positive values before the entries of the read retry data structure with negative values.
